(19) United States
(12) Patent Application Publication
(10) Pub. No.: US 2016/0154922 A1
(43) Pub. Date: Jun. 2, 2016

(54) OPTICAL PROXIMITY CORRECTION TAKING INTO ACCOUNT WAFER TOPOGRAPHY

(71) Applicant: GLOBALFOUNDRIES Inc., Grand Cayman (KY)

(72) Inventors: Rakesh Kumar Kuncha, Dresden (DE); Aravind Narayana Samy, Dresden (DE)

(21) Appl. No.: 14/556,711

(22) Filed: Dec. 1, 2014

(51) Int. Cl. G06F 17/50; G03F 1/36

(52) U.S. Cl. CPC G06F 17/5081; G06F 17/5009; G03F 1/36

(57) ABSTRACT

A method of manufacturing semiconductor devices employing optical proximity correction (OPC) is provided including providing a design layout of masks, performing OPC on the design layout to obtain a post OPC layout, performing post chemical mechanical polishing (CMP) topography simulations of a wafer to obtain the surface topography of the wafer, calculating a focus shift of a nominal focus caused by the surface topography of the wafer to obtain a shifted nominal focus, determining a process window based on the shifted nominal focus, simulating a nominal image based on the post OPC layout and the shifted nominal focus and process window images based on the post OPC layout and the process window, and identifying hotspots based on the simulated nominal and process window images.

### BACKGROUND OF THE INVENTION

1. Field of the Invention

Generally, the present disclosure relates to the field of integrated circuit manufacturing, and, more particularly, integrated circuit manufacturing that makes use of optical proximity correction.

2. Description of the Related Art

Integrated circuits formed on semiconductor wafers typically include a large number of circuit elements, which form an electric circuit. In addition to active devices such as, for example, field effect transistors and/or bipolar transistors, integrated circuits may include passive devices such as resistors, inductors and/or capacitors.

The semiconductor manufacturing process typically includes two major components, namely the Front-End-of-Line (FEOL), which includes the multilayer process of forming semiconductor devices (transistors, etc.) on a semiconductor substrate, and the Back-End-Of-Line (BEOL), which includes the metallization after the semiconductor devices have been formed. Proper electrical connection of the semiconductor devices is accomplished by multilayer metallization. Each metallization layer consists of a grid of metal lines sandwiched between one or more dielectric layers for electrical integrity. In fact, manufacturing processes may involve multiple metallization layers.

The formation of IC structures on a wafer is usually facilitated by lithographic processes used to transfer a pattern of a reticle (mask, both terms are used interchangeably herein) to a wafer. Patterns may be formed from a photoresist layer disposed on the wafer by passing light energy through a mask having an arrangement to image the desired pattern onto the photoresist layer. As a result, the pattern is transferred to the photoresist layer. In areas where the photoresist is sufficiently exposed, and after a development cycle, the photoresist material becomes soluble such that it may be removed in order to selectively expose an underlying layer (e.g., a semiconductor layer, a metal or metal-containing layer, a dielectric layer, a hard mask layer, etc.). Portions of the photoresist layer not exposed to a threshold amount of light energy will not be removed and serve to protect the underlying layer during further processing of the wafer (e.g., etching exposed portions of the underlying layer, implanting ions into the wafer, etc.). Thereafter, the remaining portions of the photoresist layer may be removed.

However, at least starting with the 45 nm node, the minimum feature size on the mask has reached sub-wavelength dimensions. Consequently, the so-called optical proximity effect caused by non-uniformity of energy intensity due to optical diffraction during the exposure process occurs. Therefore, optical proximity correction is used to solve pattern deformation caused by the optical proximity effect. The optical proximity effect due to variations in focus and exposure of the lithography process leads to parts of the design layout resulting in hot spots in the form of bridging, necking, line-end shortening, etc. Due to the formation of hot spots, printed circuits may fail certain specifications, thereby reducing the production yield.

Optical proximity correction (OPC) has been employed in order to reduce pattern deformation (hot spot formation) caused by the optical proximity effect. OPC is the process of correcting the layout of target patterns to be transferred onto a wafer using knowledge of the optical proximity effect. Generally, current OPC techniques involve running a computer simulation that takes an initial data set having information relating to the desired pattern and manipulates the data set to arrive at a corrected data set in an attempt to compensate for the above-mentioned concerns. A reticle can then be made in accordance with the corrected data set. The formed reticle may include “hammerheads” or “serifs” added to line ends to effectively anchor them in place and provide reduced pull back. Moreover, completely independent and non-resolvable assist features may be added to the mask that are intended to modify the aerial image of a nearby main feature to enhance the printability and process tolerance of that main feature. Such features can be provided in the form of scattering bars.

Briefly, the OPC process may be governed by a set of geometrical rules (i.e., “rule-based OPC” employing fixed rules for geometric manipulation of the data set), a set of modeling principles (i.e., “model-based OPC” employing predetermined behavior data to drive geometric manipulation of the data set), or a hybrid combination of rule-based OPC and model-based OPC.

OPC may be supplemented by OPC verification (U.S. Pat. No. 8,302,035) and may be improved by process window optimization (U.S. Pat. No. 7,694,267). Accordingly, a typical present-day OPC flow can be described as follows (see FIG. 1). A design data file is provided in step 100. The design data file contains information on the mask set for forming an IC, particularly the design layout of mask features of masks used in the manufacturing process. In step 110, model-based OPC is performed using a model-based OPC simulator.

Model-based OPC is performed for all masks included in the manufacturing process. The OPC processing results in a post OPC layout 120 represented by an adjusted design file. The post OPC layout is divided 130 into multiple patches representing distinct regions of the layout. The patch cutting 130 allows for further parallel processing, thereby significantly accelerating the subsequently performed nominal and processing windows simulations 140 and verification 150. For each patch obtained by the patch cutting 130, nominal and process window simulations 140 are performed. The nominal and process window simulations 140 make use of the post OPC layout for the individual patches to obtain simulated images of patterns obtained by the illumination of the masks designed according to the model-based OPC performed in step 110.

For an exposure process to pattern a device correctly, the critical dimensions (CDs) of all critical structures in the device must be patterned to achieve the design target dimensions. When a resist used in the exposure process is exposed by a projected image and thereafter baked and developed, the resist tends to undergo complex chemical and physical changes. The final resist patterns are typically characterized by their CDs, usually defined as the width of a resist feature at the resist-substrate interface. While the CD is usually intended to represent the smallest feature being patterned in the given device, in practice, the term CD is often used to describe the line width of any resist feature.

Since it is practically impossible to achieve every target CD with no errors, the device is designed with a certain tolerance for CD errors. The resulting pattern is considered to be acceptable if the CDs of all critical features are within these predefined tolerances. For the exposure process to be viable in a manufacturing environment, the full CD distribution must fall within the tolerance limits across a range of process conditions that represents the typical range of process variation expected to occur during the manufacturing process.

The range of process conditions over which the CD distribution will meet the specification limits is referred to as the “process window.” The term “nominal” may refer to the center of a process window and may be defined by the best focus and best exposure dose. At best, the focus CD and edge placement error may be equal to predetermined target values.

The process window conditions take into consideration various process variations. In lithography processing, process window conditions have typically variations in dose (relative to nominal dose), focus (relative to nominal focus) and mask bias offsets. A process may be considered to have a manufacturable process window if the CDs fall within the tolerance limits, e.g., ±10% of the nominal feature dimension, over a range of focus and exposure conditions which are expected to be maintainable in production, for example. Particularly, the nominal and process window simulations 140 are performed for best focus (nominal condition) and offset focuses with the processing window for each patch. Details of the nominal and process window simulations 140 can be found in U.S. Pat. No. 7,694,267.

The nominal and process window simulations 140 are followed by OPC verification at nominal and process window conditions 150 performed for each patch. The OPC verification 150 may include a first verification step using a CD. To this end, verification ranges are set by setting a focus value and an exposure latitude value at predetermined ranges from the best condition, with respect to the pattern layout which has undergone the optical proximity correction. In the case in which the pattern layout is transferred onto the wafer, the best condition is defined as the condition having a focus value and an exposure latitude value at which the transferred patterns are implemented exactly in the desired pattern shape. Focus and exposure dose variations can be obtained to determine the best condition in which the optical proximity correction has been exactly performed.

Types of defects, for example, necking defects or bridge defects, are set, and CD tolerance at which no defects occur is set. Defect weak points in which defects affecting device fabrication may be formed are extracted from the CD tolerance. The number of points outside of the CD tolerance in the verification range in which the focus and the exposure dose are varied (that is, the number of defect weak points detected as defects) are detected and confirmed. In order to avoid manual extraction of actually occurring hot spots from the resulting weak points, a secondary verification is performed on the defect weak points detected by the primary verification performed using the CD. The secondary verification on the defect weak points is performed using a process window. Details for this kind of two-step verification can be found in U.S. Pat. No. 8,302,035.

The OPC verification 150 results in the identification of hotspots 160 in the simulated exposure images. Then, it can be decided 170 whether the post OPC layout obtained in step 120 produces a satisfying resist pattern with respect to the occurrence of hot spots in the resulting layout. If it is decided in step 170 that the verification process of step 150 gives acceptable results in terms of identified hot spots 160, a mask set is accordingly produced 180. If it is decided in step 170 that the verification process of step 150 does not give acceptable results in terms of identified hot spots 160, the OPC recipe is amended 190 and the amended OPC recipe is used for a further model-based OPC 110.

However, practice shows that, despite the recent engineering progress, reliable identification of hot spots, particularly for wafers including topographies that significantly vary across the wafers, is still an outstanding challenge that is addressed herein.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method of manufacturing semiconductor devices employing optical proximity correction (OPC) includes the steps of providing a design layout of masks, performing OPC on the design layout to obtain a post OPC layout and performing post chemical mechanical polishing (CMP) topography simulations of a wafer to obtain the surface topography of the wafer. Moreover, the method includes calculating a focus shift of a nominal focus caused by the surface topography of the wafer to obtain a shifted nominal focus, determining a process window based on the shifted nominal focus, simulating a nominal image based on the post OPC layout and the shifted nominal focus and process window images based on the post OPC layout and the process window and identifying hotspots based on the simulated nominal and process window images.

Moreover, a method of manufacturing lithography masks is provided including the steps of providing a design layout of the masks, performing OPC on the design layout to obtain a post OPC layout, performing post chemical mechanical polishing (CMP) topography simulations of a wafer to be formed by means of the masks to obtain the surface topography of the wafer, calculating a focus shift of a nominal focus caused by the surface topography of the wafer to obtain a shifted nominal focus, determining a process window based on the shifted nominal focus, simulating a nominal image based on the post OPC layout and the shifted nominal focus and process window images based on the post OPC layout and the process window and identifying a number hotspots based on the simulated nominal and process window images. If the hot spots are not determined to cause a detrimental impact on the yield or printability, the post OPC layout is approved and producing of the masks based on the approved post OPC layout is initiated.

If the hot spots are determined to cause a detrimental impact on the yield or printability, these are identified as critical hotspots. Local OPC Fix is performed around the critical hotspots. This modified Process Window OPC recipe takes topography induced nominal focus shift into consideration. Later OPC Verification is performed locally around the hotspots.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates an OPC process flow of the prior art;

FIG. 2a illustrates the topography effect on a pattern transferred on a wafer for a design pattern shown in FIG. 2b;

FIG. 3 illustrates the effect of best focus shift due to topography for the example of the formation of an isolated feature by means of Bossung plots;

FIG. 4 illustrates an OPC process flow taking into account CMP induced wafer topography; and

FIG. 5 shows an exemplary OPC system comprising a processor and memory both configured to carry out an OPC process flow taking into account CMP induced wafer topography.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure provides methods of optical proximity correction (OPC). As will be readily apparent to those skilled in the art upon a complete reading of the present application, the present method is applicable to a variety of technologies, for example, NMOS, PMOS, CMOS, etc., and is readily applicable to a variety of devices, including, but not limited to, logic devices, memory devices, etc. The techniques and technologies described herein can be utilized to fabricate MOS integrated circuit devices, including NMOS integrated circuit devices, PMOS integrated circuit devices, and CMOS integrated circuit devices. Examples of semiconductor devices to which the herein disclosed methods may be applied include semiconductor devices exposed by I-line, KrF, ArF, ArFi or EUV wavelength, or semiconductor devices to which a binary mask, an attenuation mask, an alternate mask, or a chromeless phase shift lithography mask is applied.

Further embodiments will be described with reference to the drawings. The attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

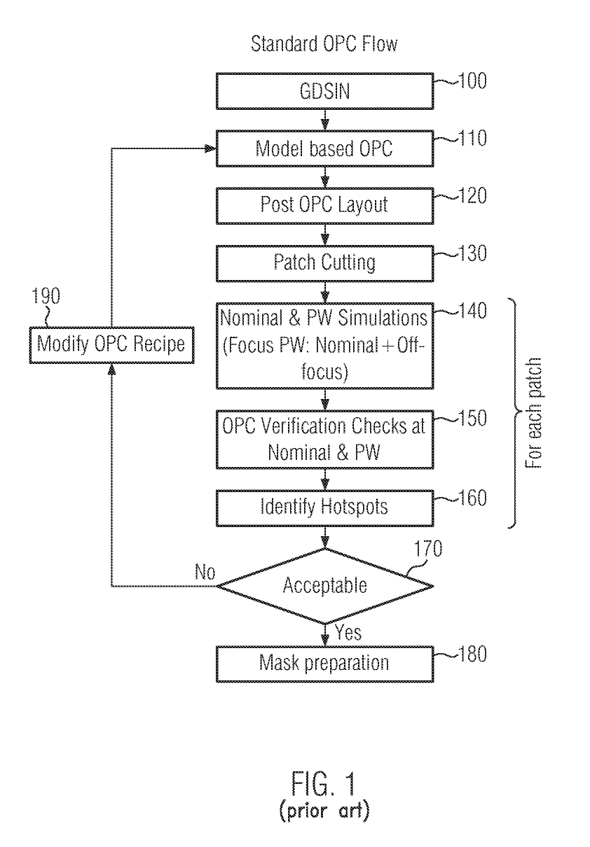

The conventional OPC process flow described above with reference to FIG. 1 does not take into account topography variations of a wafer resulting from a chemical mechanical polishing (CMP) process. Thus, the conventional OPC process flow assumes a similar nominal focus across the wafer. CMP has emerged as the predominant planarization technique for multilevel metallization. However, due to varying topographies that particularly accumulate over multiple metallization layers, locally CMP does not result in ideal planarization, giving rise to significant surface topography variations across the wafer that, in particular, impact depth of focus on the lithography process. Regions with a high density of polygon structures translate to low topography regions and regions with a relatively low density of polygon structures translate to high topology regions after CMP.

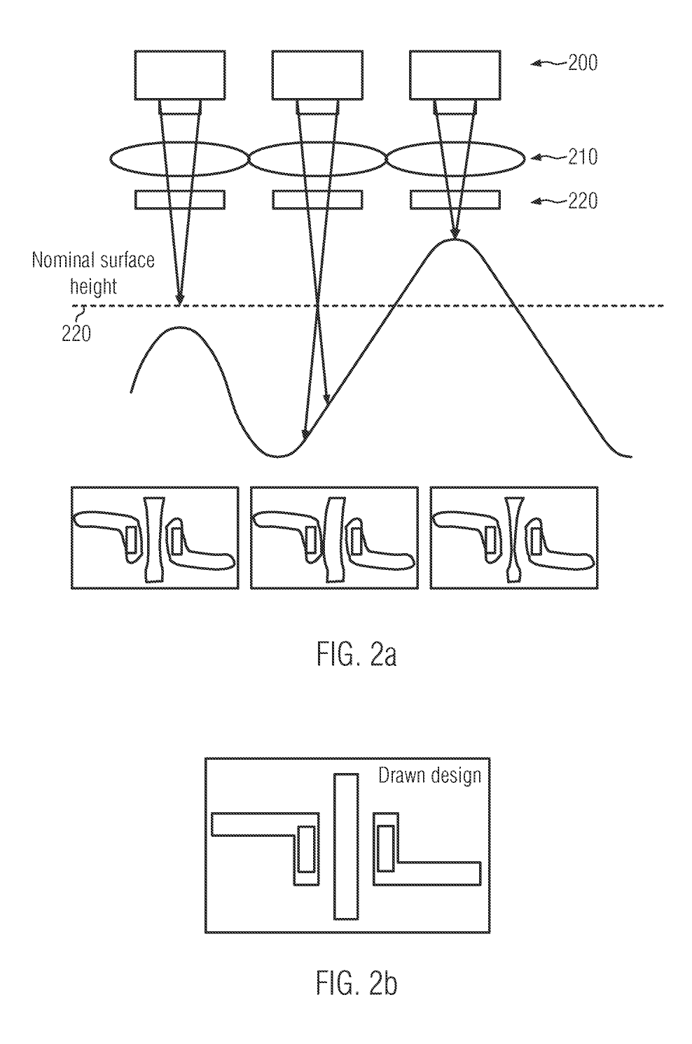

FIG. 2a illustrates the topography effect on a pattern transferred on a wafer for a design pattern shown in FIG. 2b. A lithography light source 200 is provided to illuminate through lens 210 a reticle (mask) 220. The light passed through the reticle 220 reaches a wafer having a nominal surface height 220. The left-hand side of FIG. 2a refers to a wafer surface close to the nominal surface height 220, the middle column to a low topography region and the right-hand side to a high topography region. The design pattern aimed to be transferred on the wafer is distorted in all three cases due to the optical proximity effect. In the low topography region, there is a risk for electrical shortening, whereas in the high topography region, there is a risk for open lines.

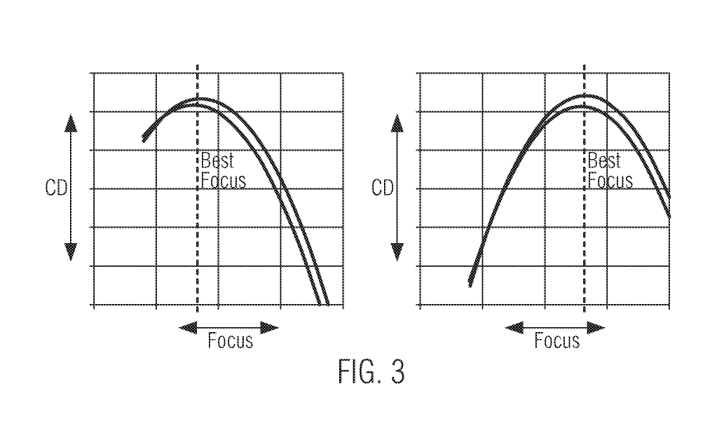

The effect of best focus shift due to topography is illustrated in FIG. 3 for the example of the formation of an isolated feature as an isolated conduction line. FIG. 3 shows Bossung plots for identifying the best focus at which the desired pattern is transferred optimally to the wafer. In the Bossung plot, the critical dimension is plotted against the focus. An isolated line structure when present at a nominal topography shows a good (large) process window centered at nominal (best) focus (see right-hand side of FIG. 3). Contrary, the same isolated line structure at a high topography region has a smaller process window and shifted best focus as shown on the left-hand-side of FIG. 3. Structures have different best focus at different topographies.

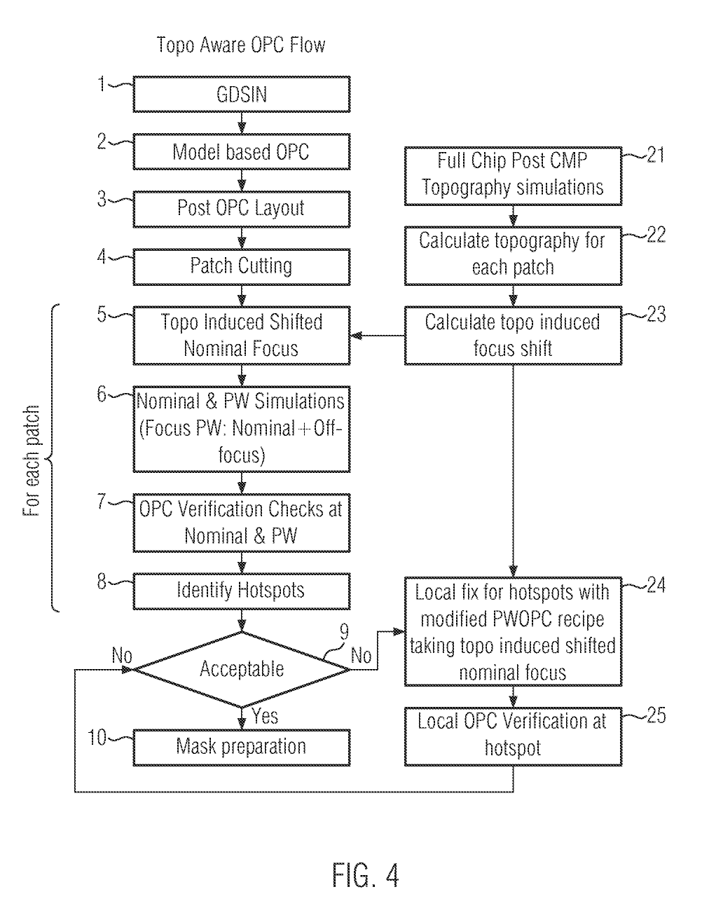

Problems as illustrated in FIGS. 2a, 2b and 3 are addressed by an improved OPC process flow as compared to the art. The improved OPC process flow taking into account CMP induced wafer topography is illustrated in FIG. 4. As in the conventional approach described above with reference to FIG. 1, in the example shown in FIG. 4, a design layout of (features of) masks of a mask set used in the manufacturing process is provided in step 1 and a model-based OPC is performed in step 2. The design layout provided in step 1 represents a pre-OPC layout. In step 1, a graphic database system (GDS) file, for example, in the GDSII format, containing mask layouts (comprising features as polygons and edges) can be provided according to an example. The model-based OPC can be performed using a model-based OPC simulator. Model-based OPC is performed for all masks included in the manufacturing process.

Model-based OPC techniques that are to be used may include, for example, line width bias corrections, corner rounding corrections, or line end pull back corrections. An optical model describing the illumination and projection optics of the exposure tool and/or an effect of imaging into a thin-film resist or the effect of the mask topography and a resist model describing the changes in the resist after being illuminated by the mask pattern in the exposure tool may also be employed. The OPC processing of step 2 results in a post OPC layout 3 represented by an adjusted design data file. Standard OPC can be used to obtain a conventional post OPC layout 3 as known in the art.

The post OPC layout is divided 4 into multiple patches. The patches may be of rectangular shape, for example. Patches of different shapes may be employed if desired. If adjacent patches exhibit relatively huge differences relative to each other with respect to the average and/or overall and/or extreme topography, it might be suitable to further sub-divide these patches. However, according to a particular example, only those patches with topography differences with respect to adjacent patches above a predetermined threshold are further partitioned that show some variations of topography above some thresholds.

If, for example, a patch neighbored by a left-hand-side patch and a right-hand-side patch shows a topography that differs from the ones of the left-hand-side and right-hand-side patches to some degree, it might be further partitioned, if its topography is relatively highly varying in terms of some appropriate statistical measure known in the art. If, however, this patch shows relatively low topography variations (for example, the extreme values are below predetermined thresholds and/or variances of an average height value of the patch are below predetermined thresholds), it might be preferred not to make such a patch smaller in order not to be faced with the necessity for global changes of the mask (post OPC layout).

Contrary to the art, topography simulations for the CMP processed entire wafer are performed 21 in order to calculate 22, for each patch, the topography induced shifts of the nominal (best) focuses (cf. illustration of focus shift in FIG. 3).

A CMP simulation model may take physical (pad property, pressure, polish time, etc.) as well as chemical effects (slurry type, removal rate, etc.) into consideration. Physical etch process, electrochemical deposition (ECD), as well as various CMP process steps for the full chip can be modeled. Calibrated post CMP topography simulations can be validated against real time wafer topography provided by measured data of a post CMP testchip. CMP simulations may be run on a production chip and the topography profile may be measured on the wafer. Then simulations topography predictions will be compared against wafer topography data for the expected accuracy of the simulation model.

The post CMP topography shows variations that result in a shift of nominal focus. Different from variations covered by the employment of process windows the post CMP variations are not randomly centered around some nominal topography but are determined by means of the topography simulations 21. For each patch, the focus shift with respect to the nominal focus for a nominal (average) topography is determined 23. For each patch the determined focus shift is added 5 to the nominal (best) focus of that patch according to the model-based OPC 2. Thus, after the step of patch cutting 4 different from the art in step 5 the topography induced shifted nominal (best) focus for each patch is determined (by means of the focus shift determined in step 23).

The further proceeding is based on the newly obtained shifted nominal focuses. As illustrated in FIG. 4 (similar to the process shown in FIG. 1), the steps of nominal and process window simulations 6 and OPC verification checks at nominal and process window conditions 7 are performed for each patch in order to identify hotspots 8. The nominal and process window simulations 6 provide images based on the post OPC layout and the shifted nominal focus and the process window. The images may represent resist images comprising resist contours. The process window conditions are calculated relative to the new (shifted) nominal focus for each patch. The OPC verification checks are performed 7 at the new (shifted) nominal and process window conditions. In principle, any kind of verification checks known in the art, for example, including verification based on CDs, can be used. In the verification step, whether the optical proximity correction is suitably or effectively performed is determined, for example, by comparing an original database of an initial pattern layout designed and drawn by a designer with the pattern layout which has undergone the optical proximity correction. Then, weak points in which defects affecting device fabrication may be formed (hot spots) are detected.

In principle, the nominal and process window simulations 6 and OPC verification checks at nominal and process window conditions 7 can be performed according to the teaching in U.S. Pat. Nos. 8,302,035 and 7,694,267, for example (though after the above-described focus shifting).

Since the known OPC procedure is basically amended by adding one constant focus shift per patch, runtime is not significantly increased.

After identification of hotspots 8, in step 9 it is determined whether or not the post OPC layout is acceptable. If it is acceptable in terms of resulting hotspots, mask production 10 can be initiated.

For example, if the CD of the identified hotspots is below a predetermined threshold and/or the hotspots are determined to cause a detrimental impact on the yield or printability (critical hotspots), the respective post OPC layout is considered not acceptable and has to be modified. If the CD of identified hotspots is above the predetermined threshold and/or if the hot spots are determined not to cause a detrimental impact on the yield or printability, mask production can be started based on the post OPC layout. If the post OPC layout is not acceptable for a patch under consideration (since, for example, bridging and/or necking and/or line-end shortening events might occur), the post OPC layout is modified 24 based on the topography induced nominal focus shift obtained in step 5 and the process window determined based on the nominal focus shift. A local OPC Fix comprises taking the post OPC layout from the previous step as input and performing OPC Fix with a modified OPC recipe in a certain region around the critical hotspots, while keeping the rest of the layout intact to generate a modified mask layout. Again, OPC verification checks are performed 25 but only for patches that are determined in step 9 not to be acceptable in terms of resulting hotspots on the wafer. Modification of the post OPC layout can be obtained by using a modified model-based OPC wherein the modifications of the modified model-based OPC take into account the shifted nominal focus. Further, the modifications of the modified model-based OPC may take into account the process window conditions for the shifted nominal focus.

The obtained masks can be used in a conventional lithography system used to image a pattern onto a wafer. The lithography system can be, for example, a step-and-repeat exposure system or a step-and-scan exposure system, but is not limited to these example systems. The lithography system may include an illuminator for directing radiation towards a mask produced according to the above-described OPC procedure. The radiation may have, for example, a deep ultraviolet wavelength (e.g., about 248 nm or about 193 nm) or a vacuum ultraviolet (VUV) wavelength (e.g., about 157 nm). The mask selectively blocks or selectively reflects the radiation provided by the illuminator such that an energy pattern defined by the mask is transferred towards the wafer. An imaging subsystem, such as a stepper assembly or a scanner assembly, sequentially directs the energy pattern transmitted by the mask to a series of desired locations on the wafer. The imaging subsystem may include a set of lenses and/or reflectors for use in scaling and directing the energy pattern towards the wafer in the form of an imaging energy pattern (exposure dose).

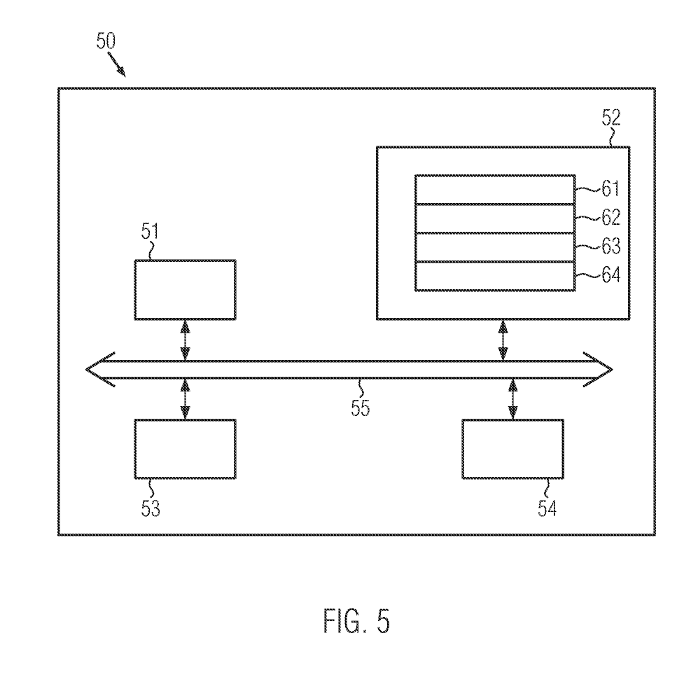

FIG. 5 is a simplified block diagram of a computer system 50 capable of implementing the method of OPC as it is described above. The computer system 50 can include one or more processors 51 used to execute instructions that carry out a specified logic routine. In addition, the computer system 50 can have a memory 52 for storing data, software, logic routine instructions, computer programs, files, operating system instructions, and the like. The memory 52 can comprise several devices and includes, for example, volatile and non-volatile memory components. As used herein, the memory 52 can include, for example, random access memory (RAM), read-only memory (ROM), hard disks, floppy disks, compact disks (e.g., CD-ROM, DVD-ROM, CD-RW, etc.), tapes, and/or other memory components, plus associated drives and players for these memory types. The processor 51 and the memory 52 may be coupled using a local interface 55. The local interface 55 can be, for example, a data bus with accompanying control bus, a network, or other subsystem.

Moreover, the computer system 51 can have various input/output (I/O) interfaces 53 as well as one or more communications interfaces 54. The I/O interfaces 53 can be used to couple the computer system 50 to various peripherals and networked devices, such as a display (e.g., a CRT display or LCD display), a keyboard, a mouse, a microphone, a camera, a scanner, a printer, a speaker, and so forth. The communication interfaces 54 can be comprised of, for example, a modem and/or network interface card, and can enable the computer system 50 to send and receive data signals, voice signals, video signals and the like via an external network, such as the Internet, a wide area network (WAN), a local area network (LAN), direct data link, or similar wired or wireless system.

The memory 52 may store an OPC model tool 61 that may work in cooperation with an OPC simulation tool 62 that can also be executed by the computer system 50. The OPC simulation tool 62 can be integral with the OPC model tool 61 or can be embodied in stand-alone software that is optionally called by the OPC model tool 61. Moreover, the memory 52 stores an OPC verification tool 63 and a post CMP topography simulation tool 64. The OPC model tool 61 may be configured to perform the model-based OPC of step 2 of FIG. 4 and make use of an OPC model also stored in the memory 52. The OPC model tool 61 may employ an OPC library that might also be stored in the memory 52. The OPC simulation tool 62 may be configured to perform the nominal and process window simulations based on the shifted nominal focus for each patch as described with reference to step 6 of FIG. 4. The

OPC verification tool 63 may be configured to perform the verification checks of step 7 of FIG. 4 and the post CMP topography simulation tool 64 may be configured to perform the simulations of step 21 of FIG. 4 in order to calculate the topography for each patch after CMP and the topography induced focus shift in accordance with steps 22 and 23 of FIG. 4. In particular, the OPC model tool 61 may be configured to modify the post OPC layout based on the topography induced nominal focus shift and the process window determined based on the nominal focus shift as described in step 24 of FIG. 4.

In one embodiment, the OPC model tool 61 and/or the OPC simulation tool 62 and/or the OPC verification tool 63 and/or post CMP topography simulation tool 64 are embodied as one or more computer programs (e.g., one or more software applications including compilations of executable code). The computer program(s) can be embodied on (i.e., stored by) a computer readable medium, such as a magnetic, optical or semiconductor storage device (e.g., hard disk, CD-ROM, DVD-ROM, flash memory, etc.).

Further, the memory 52 may store an operating system (not shown) that is executed by the processor 51 to control the allocation and usage of resources in the computer system 50. Specifically, the operating system controls the allocation and usage of the memory 52, the processing time of the processor 51 dedicated to various applications being executed by the processor 51, and the peripheral devices, as well as performing other functionality. In this manner, the operating system serves as the foundation on which applications, such as the OPC model tool 61 and/or the OPC simulation tool 62 and/or the OPC verification tool 63 and/or post CMP topography simulation tool 64, depend, as is generally known by those with ordinary skill in the art.

Portions of the description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical or magnetic signals capable of being stored, transferred, combined, compared and otherwise manipulated. It has proven convenient at times, principally for reasons of common usage, to refer to these signals as bits, values, elements, symbols, characters, terms, numbers or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or the like refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

As a result, herein are provided methods of OPC and a system implementing those methods that allow for a reliable identification of hot spots on wafers taking into account CMP induced topographies. In current technologies, in higher metal layers, the particular CMP topography involved becomes a major issue when trying to detect hotspots. Here, CMP induced variations significantly contribute to limitations of the overall processing window resulting in different best focuses for structures exhibiting different topographies. Particularly, hotspots that might not occur for some nominal topography might become critical in low or high topographies. The methods described herein allow for taking into account focus shifts due to variances in the topography across a wafer caused by imperfect CMP planarization, thereby improving the manufacturable processing window and, thus, the production yield.

It should be noted that local OPC fixes (modification of OPC models) can be calculated for individual patches rather than changing the entire (simulated) mask. Thereby, reliability and stability of the overall OPC process can be increased since boundary healing problems, etc. have not to be newly addressed as it were the case for running a topography aware modification of OPC models for the entire wafer. Moreover, overall runtime is not significantly enhanced as compared to conventional OPC processing, since OPC fixes can be run locally (for an individual patch if need be).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention.

Accordingly, the protection sought herein is as set forth in the claims below.

What is claimed:

1. A method of manufacturing of semiconductor devices employing optical proximity correction (OPC), comprising:
providing a design layout of masks;
performing OPC on said design layout to obtain a post OPC layout;
performing post chemical mechanical polishing (CMP) topography simulations of a wafer to obtain a surface topography of said wafer;
calculating a focus shift of a nominal focus caused by said surface topography of said wafer to obtain a shifted nominal focus;
determining a process window based on said shifted nominal focus;
simulating a nominal image based on said post OPC layout and said shifted nominal focus and process window images based on said post OPC layout and said process window; and
identifying hotspots based on said simulated nominal and process window images.

2. The method of claim 1, further comprising performing OPC verification on said simulated nominal and process window images to identify said hotspots.

3. The method of claim 1, further comprising dividing said post OPC layout into multiple patches and wherein for each of said multiple patches:
a shifted nominal focus is calculated;
a process window based on said shifted nominal focus is determined;
a nominal image based on said post OPC layout and said shifted nominal focus and process window images based on said post OPC layout and said process window are simulated; and
hotspots are identified based on said simulated nominal and process window images.

4. The method of claim 3, further comprising performing, for each patch, OPC verification on said simulated nominal and process window images to identify said hotspots.

5. The method of claim 3, wherein a patch is divided into further patches if its topography variations exceed some predetermined threshold.

6. The method of claim 3, wherein if the surface topography of a first patch differs from the surface topography of a second patch adjacent to said first patch by a predetermined measure:
a) said first patch is further divided into patches if the surface topography of said first patch varies more than a predetermined variation threshold; and
b) said first patch is not further divided into patches if the surface topography of said first patch varies not more than a predetermined variation threshold.

7. The method of claim 2, wherein performing said OPC verification comprises verification based on a critical dimension.

8. The method of claim 1, wherein said hotspots comprise at least one of bridging, necking and line-end shortening features.

9. The method of claim 1, further comprising, if any of the identified hotspots is determined to cause a detrimental impact on the yield or printability, modifying said post OPC layout locally around the thus determined hotspots taking into account said shifted nominal focus.

10. The method of claim 9, wherein said post OPC layout is modified by means of a modified OPC recipe taking into account said shifted nominal focus.

11. The method of claim 9, further comprising simulating a nominal image and process window images based on said modified post OPC layout and identifying hotspots based on the thus simulated nominal and process window images.

12. The method of claim 3, further comprising, if in a particular patch any of the identified hot spots is determined to cause a detrimental impact on the yield or printability, modifying said post OPC layout of that particular patch locally around the thus determined hotspots taking into account said shifted nominal focus.

13. The method of claim 12, further comprising simulating a nominal image and process window images based on said modified post OPC layout of that particular patch and identifying hotspots in that particular patch based on the thus simulated nominal and process window images.

14. A method of manufacturing lithography masks, comprising
providing a design layout of the masks;
performing OPC on said design layout to obtain a post OPC layout;
performing post chemical mechanical polishing (CMP) topography simulations of a wafer to be formed by means of said masks to obtain a surface topography of said wafer;
calculating a focus shift of a nominal focus caused by said surface topography of said wafer to obtain a shifted nominal focus;
determining a process window based on said shifted nominal focus;
simulating a nominal image based on said post OPC layout and said shifted nominal focus and process window images based on said post OPC layout and said process window;
identifying a number of hotspots based on said simulated nominal and process window images; and
if none of said identified hotspots is determined to cause a detrimental impact on the yield or printability:
approving said post OPC layout and producing said masks based on said approved post OPC layout.

15. The method of claim 14, further comprising performing OPC verification on said simulated nominal and process window images to identify said hotspots.

16. The method of claim 14, further comprising dividing said post OPC layout into multiple patches and wherein for each of said multiple patches:
a shifted nominal focus is calculated;
a process window based on said shifted nominal focus is determined;
a nominal image based on said post OPC layout and said shifted nominal focus and process window images based on said post OPC layout and said process window are simulated; and
hotspots are identified based on the thus simulated nominal and process window images.

17. The method of claim 16, further comprising performing, for each patch, OPC verification on said simulated nominal and process window images to identify said hotspots in each patch.

18. The method of claim 14, further comprising, if any of said identified hot spots is determined to cause a detrimental impact on said yield or printability:
modifying said post OPC layout taking into account said shifted nominal focus;
simulating a nominal image based on said modified post OPC layout and said shifted nominal focus and process window images based on said modified post OPC layout and said process window;
identifying a number of hotspots based on the thus simulated nominal and process window images, and if the number of the thus identified hotspots does not exceed a predetermined threshold, approving said modified post OPC layout and producing said masks based on said approved modified post OPC layout.

19. The method of claim 16, further comprising if, in a particular patch, any of said identified hotspots is determined to cause a detrimental impact on said yield or printability, modifying said post OPC layout of that particular patch locally around the thus determined hotspots using a modified process window OPC recipe taking into account said shifted nominal focus.

20. The method of claim 16, further comprising, if any of said identified hotspots is determined to cause a detrimental impact on said yield or printability for a particular patch:
modifying said post OPC layout for that patch locally around the thus determined hotspots using a modified process window OPC recipe taking into account said shifted nominal focus;
simulating a nominal image based on said modified post OPC layout and said shifted nominal focus and process window images based on said modified post OPC layout and said process window; and
identifying a number of hotspots based on the thus simulated nominal and process window images, and, if the number of the thus identified hotspots does not exceed a predetermined threshold, approving said modified post OPC layout and producing said masks based on said approved modified post OPC layout.

21. The method of claim 16, further comprising, if any of said identified hotspots is determined as a critical hotspot, i.e., identified to cause a detrimental impact on said yield or printability for a particular patch:
performing a local OPC fix by modifying said post OPC layout for that patch locally around the thus determined hotspots using a modified process window OPC recipe taking into account said shifted nominal focus, wherein performing said local OPC fix comprises taking the post OPC layout obtained by performing the OPC on the design layout as input and performing the OPC fix with a modified OPC recipe in a certain region around the critical hotspots, while keeping the rest of the post OPC layout intact to generate a modified mask layout.

22. The method of claim 16, further comprising performing, for each patch, OPC verification on said simulated nominal and process window images to identify said hotspots.

23. The method of claim 14, wherein a patch is divided into further patches if its topography variations exceed some predetermined threshold.

24. The method of claim 14, wherein, if the surface topography of a first patch differs from the surface topography of a second patch adjacent to said first patch by a predetermined measure:
a) said first patch is further divided into patches if said surface topography of said first patch varies more than a predetermined variation threshold; and
b) said first patch is not further divided into patches if said surface topography of said first patch varies not more than a predetermined variation threshold.
